(19) United States
(12) Patent Application Publication
(10) Pub. No.: US 2005/0195984 A1
(43) Pub. Date: Sep. 8, 2005

(54) Sound reproducing method and apparatus

(76) Inventors: Masayoshi Miura, Chiba (JP); Susumu Yabe, Tokyo (JP); Yoichiro Sako, Tokyo (JP); Toshiro Terauchi, Tokyo (JP)

Correspondence Address: FROMMER LAWRENCE & HAUG LLP, 745 FIFTH AVENUE, NEW YORK, NY, 10151, US

(21) Appl. No.: 11/068,709

(22) Filed: Mar. 1, 2005

(30) Foreign Application Priority Data
Mar. 2, 2004 (JP) 2004-057814

(51) Int. Cl. H03G 3/00

(52) U.S. Cl. 381/63; 381/61

(57) ABSTRACT

A sound producing apparatus includes a sound data reproduction unit that reproduces sound data, a meta-data analyzer that analyzes meta-data indicating the properties of the sound data, a room acoustic characteristic analyzer that measures an acoustic characteristic of a listening room, and a reproduction characteristic adjuster. The reproduction characteristic adjuster performs an acoustic characteristic adjustment on the sound data to be reproduced based on the room acoustic characteristic data obtained by the room acoustic characteristic analyzer and the acoustic characteristic data obtained by the meta-data analyzer.

### BACKGROUND OF THE INVENTION

1. Field of the Invention

The present invention relates to a sound reproducing method and apparatus. More specifically, the present invention relates to a sound reproducing method suitable for sound reproduction in a listening room, e.g., reproduction of a music source recorded in a concert hall, and to a sound reproducing apparatus capable of sound reproduction using the sound reproducing method.

2. Description of the Related Art

Generally, acoustic characteristics of listening rooms differ from each other depending upon the room size, shape, and interior. An acoustic characteristic of a listening room is corrected using a sound reproducing apparatus so as to become close to a standard acoustic characteristic or an acoustic characteristic according to the listener's preference.

For example, one sound reproducing apparatus emits into the listening room a measurement signal for measuring an acoustic characteristic and collects a response (reflected sound) to the measurement signal to determine the acoustic characteristic of the listening room. The apparatus further obtains a correction characteristic for correcting the acoustic characteristic in the listening room from the determined room acoustic characteristic, and corrects a reproduction signal based on the obtained correction characteristic (see Japanese Unexamined Patent Application Publication No. 6-327089).

In order to measure an acoustic characteristic of a listening room or the like, it is necessary to determine the transfer function from a sound source to a listening point. In a listening room, a loudspeaker of an acoustic reproducing apparatus is the sound source.

For example, in the intensity stereo method, two front right and left loudspeakers are the sound sources. For example, in the 5.1 channel method, five loudspeakers composed of two front right and left loudspeakers, one front center loudspeaker, and two rear right and left loudspeakers are the sound sources. When loudspeakers are the sound sources, measurement is performed on each speaker channel independently. The transfer function for all channels driven is determined by calculating the sum of the transfer functions for the respective channels.

A microphone having the same directional characteristic as that of a listener or a closely located four point microphone capable of finding the sound source position is used as a microphone for measurement, which is located at a listening point (see “Kinsetsu 4-ten Hou ni yoru Konsato Horu no Onkyo Sokutei (Acoustic Measurement of Concert Hall by Closely Located Four Point Microphone Method),” Yoshio Yamasaki and Takeshi Ito, JAS Journal, October, 1987).

One microphone having the same directional characteristic as that of a listener is a dummy-head microphone. A simpler configuration is that microphones are embedded in a surface of a head-like spheroid at opposite sides thereof, which resembles the human ears.

Another proposed approach is to obtain information about the installation and characteristic adjustment for an audio system via a network so that the audio system automatically performs an acoustic characteristic adjustment.

For example, a central server and an audio system connected to the central server via a communication network constitute a service system. The central server transmits data for adjusting and installing the audio system to the audio system. The audio system automatically performs an acoustic characteristic adjustment using the received adjustment data. The audio system further displays the received installation data to allow a user to install the audio system in a vehicle according to the displayed installation method (see Japanese Unexamined Patent Application Publication No. 2002-67815).

Interaural cross-correlation coefficients in diffuse sound fields are described in “Kakusan oyobi Saisei Onba ni okeru Ryoji kan Soukan Keisuu (Interaural Cross-Correlation Coefficients in Diffuse and Reproduced Sound Fields),” Mikio Toyama, et al., Transactions of Technical Committee of Psychological and Physiological Acoustics of the Acoustical Society of Japan, H-84-28, 1984.

However, listeners may listen to a wide variety of music sources in a listening room, and the required acoustic characteristic depends upon the category of the music source and the recording conditions of reflected sounds and reverberant sounds recorded in a concert hall. Traditional sound reproducing apparatuses require a user to perform a time-consuming operation to adjust the acoustic characteristic each time a music source is changed, depending upon the category and recording environment of the music source.

### SUMMARY OF THE INVENTION

Accordingly, it is an object of the present invention to provide a sound reproducing method and apparatus for realizing the optimum acoustic characteristic based on an acoustic characteristic of a reproduced sound field space, such as a listening room, and an acoustic characteristic of a sound source.

In one aspect of the present invention, a sound reproducing method includes obtaining an acoustic characteristic of a space in which sound data is to be reproduced, obtaining a target acoustic characteristic of a reproduced sound field space associated with the sound data, and performing an acoustic characteristic adjustment based on the acoustic characteristic of the space in which sound data is to be reproduced and the target acoustic characteristic of the reproduced sound field space when the sound data is reproduced.

In another aspect of the present invention, a sound reproducing apparatus includes a sound data reproducing unit that reproduces sound data, an acoustic characteristic obtaining unit that obtains a target acoustic characteristic of a reproduced sound field space associated with the sound data, an acoustic characteristic measuring unit that measures a room acoustic characteristic of a space in which the sound data is to be reproduced, and an acoustic characteristic adjusting unit that performs an acoustic characteristic adjustment based on the room acoustic characteristic measured by the acoustic characteristic measuring unit and the target acoustic characteristic obtained by the acoustic characteristic obtaining unit when the sound data is reproduced.

According to the present invention, an acoustic characteristic adjustment for reproduction of sound data can be performed based on an acoustic characteristic of a space in which the sound data is to be reproduced and an acoustic characteristic of a reproduced sound field space associated with the sound data.

The present invention allows an acoustic characteristic adjustment for sound reproduction based on an acoustic characteristic of a listening room and an acoustic characteristic of a space in which sound data of a music source to be reproduced was recorded. If music sources having different recording environments and various categories are reproduced by a sound reproducing apparatus, an adjustment to an optimum acoustic characteristic for each music source can automatically be performed without performing an acoustic characteristic adjustment on the user side.

### BRIEF DESCRIPTION OF THE DRAWINGS

FIG. 1 is a block diagram of a sound reproducing apparatus according to an embodiment of the present invention;

FIGS. 2A and 2B are illustrations showing parameters indicating the properties of a reproduced sound field space recorded in form of meta-data in a recording medium;

FIGS. 3A and 3B are block diagrams of acoustic characteristic measurement devices in the sound reproducing apparatus according to the embodiment;

FIG. 4 is an illustration of a listening room;

FIG. 5 is a diagram of a reproduction characteristic adjuster;

FIG. 6 is a diagram of another reproduction characteristic adjuster;

FIG. 7 is a diagram of a canceling filter;

FIG. 8 is a block diagram of a sound reproducing apparatus according to another embodiment of the present invention; and

FIG. 9 is a block diagram of a sound reproducing apparatus according to still another embodiment of the present invention.

### DESCRIPTION OF THE PREFERRED EMBODIMENTS

Embodiments of the present invention will now be described.

In the following description, a recording medium, e.g., an optical disc, stores sound data and meta-data indicating the properties of a space in which the sound data is to be reproduced. The sound data has been recorded by a microphone close to the source of sound so that it does not include a reflected sound and a reverberant sound.

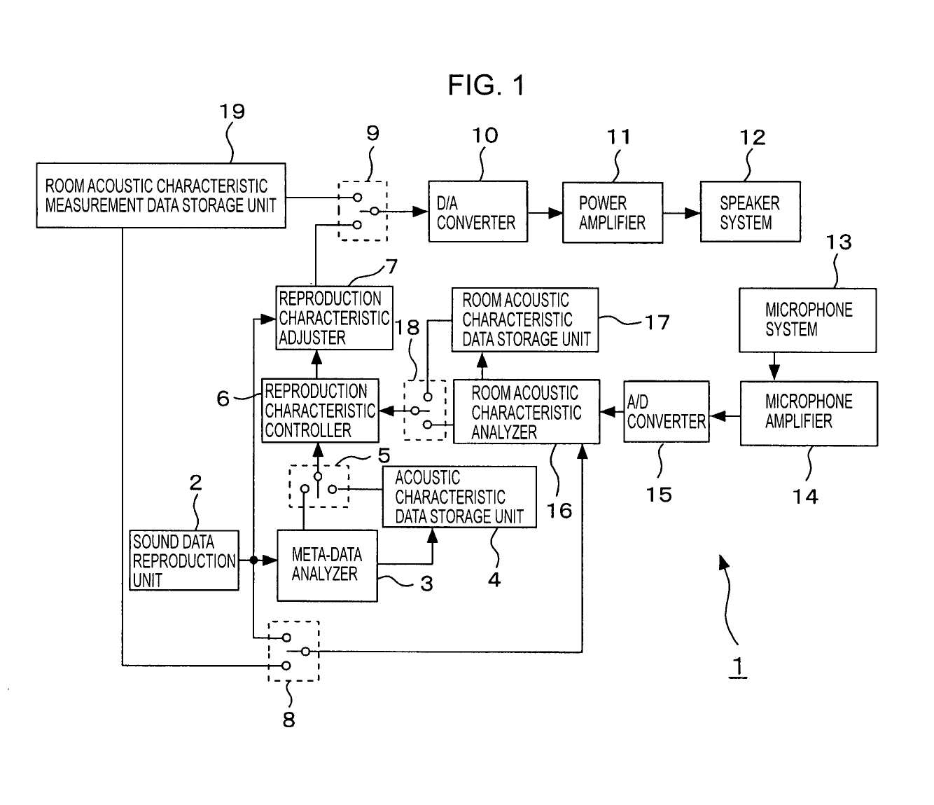

A sound reproducing apparatus 1 according to an embodiment of the present invention will now be described with reference to FIGS. 1 to 7.

FIG. 1 is a block diagram of the sound reproducing apparatus 1.

In FIG. 1, a sound data reproduction unit 2 reads sound data recorded in a recording medium (not shown), and decodes the read sound data for sound reproduction.

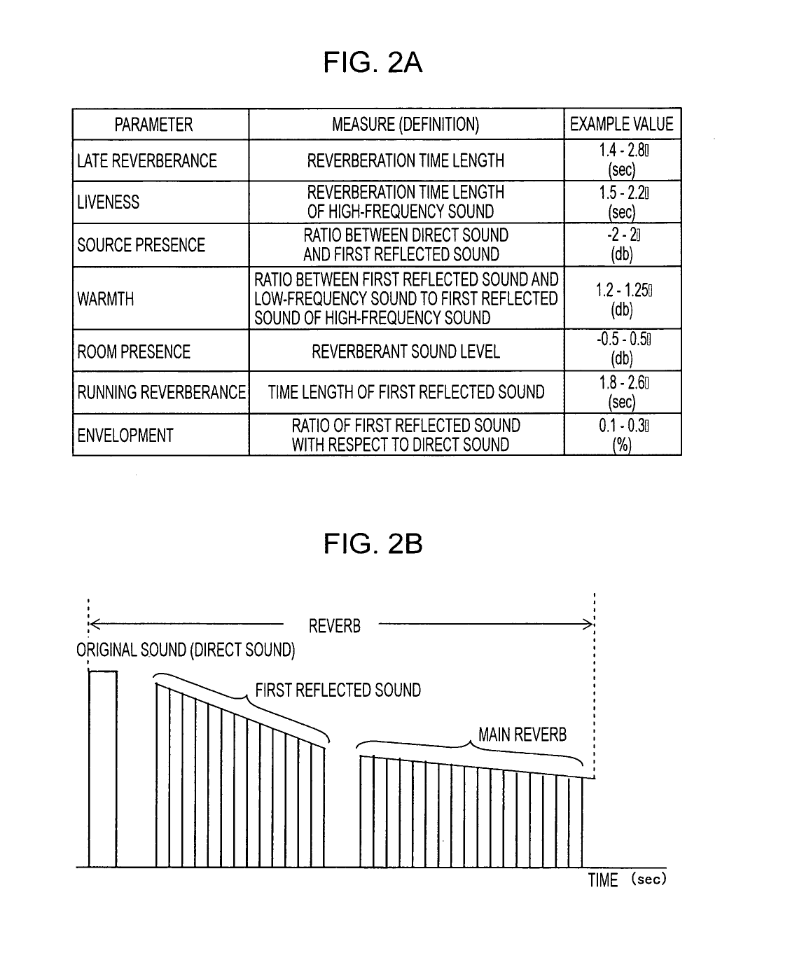

A meta-data analyzer 3 obtains meta-data recorded in the recording medium via the sound data reproduction unit 2. The obtained meta-data is analyzed to determine an acoustic characteristic of a listening room so as to provide the optimum reproduced sound field space for reproduction of the sound data recorded in the recording medium. The properties of the reproduced sound field space recorded in the form of meta-data in the recording medium are shown in FIG. 2A.

The properties of the reproduced sound field space are represented by reverbs. As shown in FIG. 2B, a reverb is represented by the original sound (or direct sound), the first reflected sound, and the reverberant sound that is the main reverb.

FIG. 2A shows parameters indicating the properties of the reproduced sound field space and the measures (definitions) of the parameters.

A late reverberance is represented by the reverberation time from the direct sound to the main reverb, and has a value of, for example, 1.4 to 2.8 (in sec).

A liveness is represented by the reverberation time of a high-frequency sound, and has a value of, for example, 1.5 to 2.2 (in sec).

A source presence is represented by the ratio between the direct sound and the first reflected sound, and has a value of, for example, −2 to 2 (in dB).

A warmth is represented by the ratio between the first reflected sound of a low-frequency sound and the first reflected sound of a high-frequency sound, and has a value of, for example, 1.2 to 1.25 (in dB).

A room presence is represented by the level of the reverberant sound, and has a value of, for example, −0.5 to 0.5 (in dB).

A running reverberance is represented by the reverberation time of the first reflected sound, and has a value of, for example, 1.8 to 2.6 (in sec).

An envelopment is represented by the ratio of the first reflected sound with respect to the direct sound, and has a value of, for example, 0.1 to 0.3 (in %).

An acoustic characteristic data storage unit 4, which may be a memory, stores the acoustic characteristic data analyzed by the meta-data analyzer 3.

A switch 5 is a switch for selecting acoustic characteristic data corresponding to the sound data to be supplied to a reproduction characteristic controller 6. The switch 5 selects the acoustic characteristic data stored in the acoustic characteristic data storage unit 4 or the acoustic characteristic data output from the meta-data analyzer 3.

A reproduction characteristic adjuster 7 performs an acoustic characteristic adjustment on the sound data reproduced by the sound data reproduction unit 2 under the control of the reproduction characteristic controller 6.

The reproduction characteristic controller 6 controls the reproduction characteristic adjuster 7 based on the acoustic characteristic data input from the meta-data analyzer 3 or the acoustic characteristic data storage unit 4 via the switch 5 and the room acoustic characteristic data of the listening room. The room acoustic characteristic data is input from a switch 18. A process for obtaining the acoustic characteristic data of the listening room is described below.

A switch 8 selectively supplies acoustic characteristic measurement data stored in a room acoustic characteristic measurement data storage unit 19, described below, or the sound data of the sound data reproduction unit 2 to a room acoustic characteristic analyzer 16.

A switch 9 selectively supplies the sound data from the reproduction characteristic adjuster 7 or the acoustic characteristic measurement data from the room acoustic characteristic measurement data storage unit 19, described below, to a digital-to-analog (D/A) converter 10.

The D/A converter 10 converts a digital signal (sound data or acoustic characteristic measurement data) input via the switch 9 into an analog signal (sound signal or acoustic characteristic measurement signal), and outputs the converted analog signal to a power amplifier 11.

The power amplifier 11 amplifies the analog signal from the D/A converter 10 to a predetermined level. A speaker system 12 outputs the signal amplified by the power amplifier 11 as an audible sound.

A microphone system 13 is located at a predetermined listening point for collecting sound at this point when measuring the room acoustic characteristic of the listening room.

A microphone amplifier 14 amplifies the collected sound signal obtained by the microphone system 13, and outputs the amplified signal to an analog-to-digital (A/D) converter 15.

The A/D converter 15 converts the analog collected sound signal from the microphone amplifier 14 into a digital collected sound signal, and outputs the converted digital signal to the room acoustic characteristic analyzer 16.

The room acoustic characteristic analyzer 16 analyzes the collected sound data input via the A/D converter 15 using the signal input via the switch 8 as a reference signal to determine the room acoustic characteristic of the listening room.

A room acoustic characteristic data storage unit 17, which may be a memory, stores the room acoustic characteristic data obtained by the room acoustic characteristic analyzer 16.

The switch 18 is a switch for selecting acoustic characteristic data of the listening room to be supplied to the reproduction characteristic controller 6. The switch 18 selectively supplies the acoustic characteristic data stored in the room acoustic characteristic data storage unit 17 or the acoustic characteristic data directly output from the room acoustic characteristic analyzer 16.

The room acoustic characteristic measurement data storage unit 19 stores measurement data for measuring the room acoustic characteristic of the listening room. The measurement data may be an M-sequence signal (Maximum Length Sequence), a TSP (Time Stretched Pulse) signal, or the like.

The overall sound reproducing apparatus 1 and the switches 5, 8, 9, and 18 are controlled a system controller (not shown).

The sound reproducing apparatus 1 performs an acoustic characteristic adjustment on the sound data based on the acoustic characteristic obtained from the meta-data recorded in the recording medium and the actual room acoustic characteristic of the listening room. Thus, the sound reproducing apparatus 1 includes the meta-data analyzer 3 serving as an acoustic characteristic obtaining device that is configured to obtain the acoustic characteristic corresponding to the sound data, and an acoustic characteristic measurement device that is configured to measure the room acoustic characteristic of the listening room.

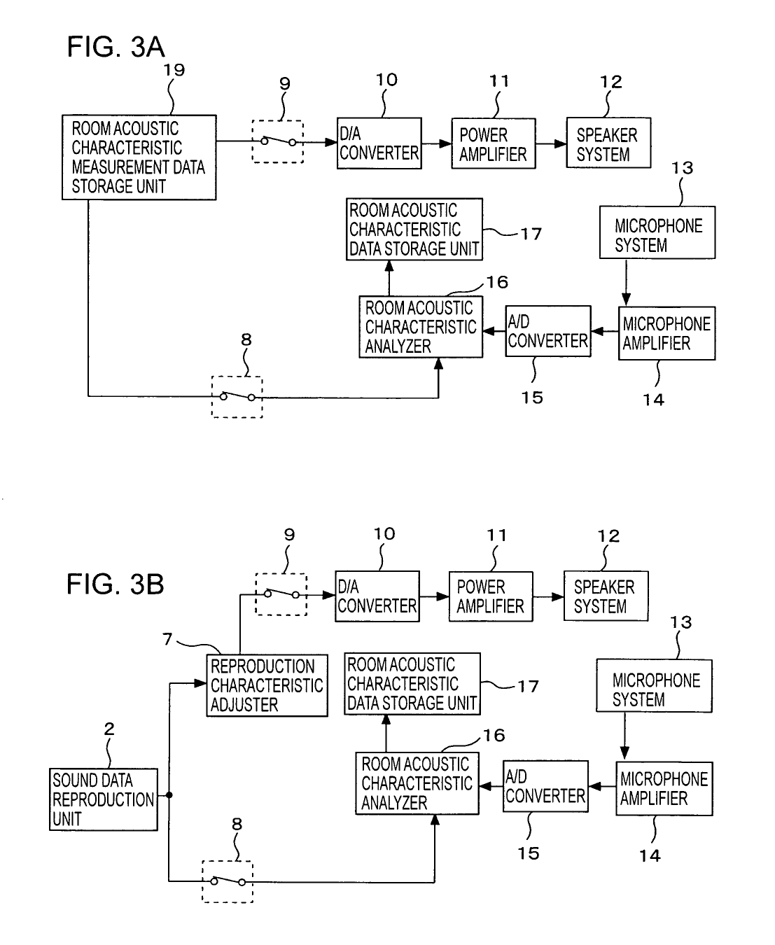

FIGS. 3A and 3B are block diagrams of acoustic characteristic measurement devices in the sound reproducing apparatus 1 shown in FIG. 1.

FIG. 3A shows an acoustic characteristic measurement device including the room acoustic characteristic measurement data storage unit 19. In this device, sound source data meeting measurement particulars is selectively read from the room acoustic characteristic measurement data storage unit 19. The read measurement data is transmitted to the D/A converter 10 via the switch 9, and the measurement data converted by the D/A converter 10 is amplified by the power amplifier 11. The amplified measurement signal is output from the speaker system 12.

The sound output from the speaker system 12 is collected by a microphone in the microphone system 13 located at a predetermined measurement point in the listening room.

The collected sound signal output from the microphone in the microphone system 13 is amplified by the microphone amplifier 14, and the amplified collected sound signal is transmitted to the room acoustic characteristic analyzer 16 after it is converted by the A/D converter 15.

The room acoustic characteristic analyzer 16 analyzes the collected sound data using as reference data the measurement data input from the room acoustic characteristic measurement data storage unit 19 via the switch 8, and obtains the acoustic characteristic (i.e., the transfer function) of the listening room.

The analysis result of the room acoustic characteristic analyzer 16 is stored in the room acoustic characteristic data storage unit 17.

The reason that the room acoustic characteristic analyzer 16 determines the transfer function of the listening room using the measurement data stored in the room acoustic characteristic measurement data storage unit 19 as reference data will now be described.

Basically, when an impulse response to a measurement sound signal output from the speaker system 12 is collected using the microphone system 13, the collected sound signal obtained by the microphone system 13 represents the transfer function of the listening room. However, it is difficult to increase the signal-to-noise (S/N) ratio.

In the present embodiment, a high-energy signal is used as measurement data, and the room acoustic characteristic analyzer 16 determines the transfer function of the listening room by dividing the collected sound data (response signal) input via the A/D converter 15 by the measurement data input via the switch 8.

According to Toyama, et al., in the publication noted above, it is determined whether or not the sound field is naturally diffuse by analyzing the cross-correlation coefficient between two omnidirectional microphones that are spaced by an equivalent interaural distance (about 30 cm). For example, cross-correlation coefficients with respect to some variations in the reproduction characteristic are measured at a listening point, thus allowing the room acoustic characteristic analyzer 16 to determine room acoustic characteristic data that meets more naturally-diffuse sound field conditions.

The room acoustic characteristic measurement data generated from the room acoustic characteristic measurement data storage unit 19 may be generated each time by a computation device, such as a digital signal processor (DSP).

FIG. 3B shows another acoustic characteristic measurement device that does not include the room acoustic characteristic measurement data storage unit 19.

In this device, the sound data reproduced by the sound data reproduction unit 2 is used as measurement data. The sound data reproduced by the sound data reproduction unit 2 is transmitted to the D/A converter 10 via the reproduction characteristic adjuster 7 and the switch 9, and the sound data converted by the D/A converter 10 is amplified by the power amplifier 11. The amplified sound signal is output from the speaker system 12.

Also in this device, the sound output from the speaker system 12 is collected by a microphone in the microphone system 13. The collected sound signal output from the microphone in the microphone system 13 is amplified by the microphone amplifier 14, and the amplified collected sound signal is transmitted to the room acoustic characteristic analyzer 16 after it is converted by the A/D converter 15.

The room acoustic characteristic analyzer 16 performs analysis according to measurement particulars using the sound data input from the sound data reproduction unit 2 via the switch 8, and obtains the acoustic characteristic (i.e., the transfer function) of the listening room that is a reproduced sound field space.

The analysis result of the room acoustic characteristic analyzer 16 is stored in the room acoustic characteristic data storage unit 17. Also in this device, the collected sound data (response signal) is divided by the sound data (input signal) to determine the transfer function. The room acoustic characteristic data storage unit 17 may store a standard room acoustic characteristic in advance.

In the sound reproducing apparatus 1 according to the present embodiment, the room acoustic characteristic of the listening room is measured, and an acoustic characteristic adjustment is performed by the reproduction characteristic adjuster 7 on the sound data reproduced by the sound data reproduction unit 2 based on the measured acoustic characteristic of the listening room and the meta-data acoustic characteristic stored in the recording medium.

Therefore, the sound reproducing apparatus 1 according to the present embodiment allows an acoustic characteristic adjustment for reproduction of a sound signal of a music source based on a room acoustic characteristic of a listening room and a target space acoustic characteristic for reproduction of the sound signal.

Thus, if music sources having different recording environments and various categories are reproduced by the sound reproducing apparatus 1, an adjustment to an optimum acoustic characteristic for each music source can automatically be performed without performing an acoustic characteristic adjustment on the user side.

The acoustic characteristic by which a listening room affects a sound image will now be described.

For example, one listening room type that affects the acoustic characteristic is a listening room having a horizontally asymmetrical acoustic space.

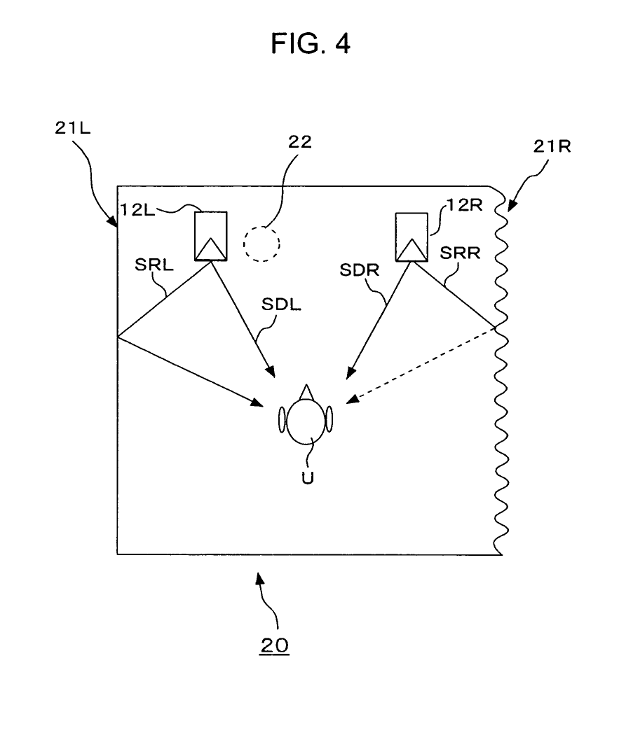

FIG. 4 illustrates a listening room 20 having such an asymmetric acoustic space.

In the listening room 20 shown in FIG. 4, a right wall 21R has higher sound absorption than a left wall 21L with respect to a listener U, and there is substantially no reflected sound from the right wall 21R. That is, the right and left walls 21R and 21L have largely different surface reflection properties from each other.

When a sound reaching the listener U from a left loudspeaker 12L at the front left position with respect to the listener U is compared with a sound reaching the listener U from a right loudspeaker 12R at the front right position with respect to the listener U, direct sounds SDR and SDL reaching the listener U from the loudspeakers 12L and 12R are substantially the same. However, reflected sounds SRR and SRL reflected by the right and left walls 21R and 21L largely differ from each other. In this case, a sound image 22, such as a vocalist or a main instrument, which is to be localized substantially at the center between the right and left loudspeakers 12R and 12L, may be shifted to the high-reflection side (in FIG. 4, to the left), or an excessively noticeable echo may be produced from a certain side. Therefore, the sound image 22 in the listening room 20 may be largely affected.

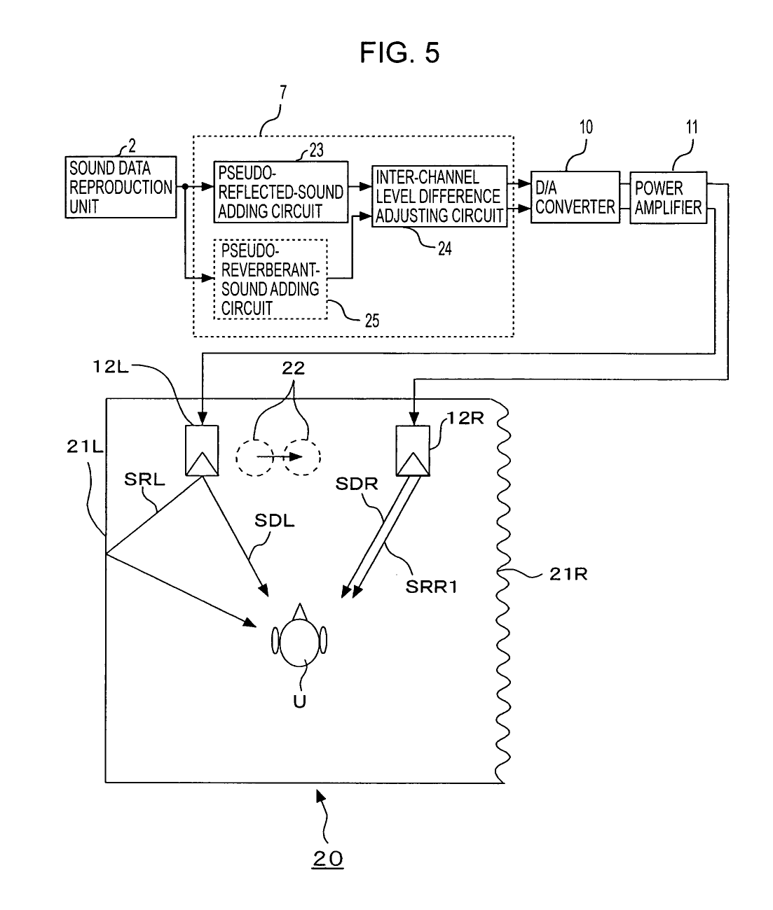

In order to overcome such a problem, in the sound reproducing apparatus 1 according to the present embodiment, the reproduction characteristic adjuster 7 has an arrangement shown in FIG. 5 for adjusting the sound data.

The reproduction characteristic adjuster 7 shown in FIG. 5 includes a pseudo-reflected-sound adding circuit 23 and an inter-channel level difference adjusting circuit 24. When there is substantially no reflected sound from the right wall 21R of the listening room 20, the pseudo-reflected-sound adding circuit 23 adds pseudo-reflected-sound data to the sound data output from the right loudspeaker 12R, and the inter-channel level difference adjusting circuit 24 adjusts the level difference between the right and left channels.

Therefore, if the reflected sound SRR is not reflected from the right wall 21R of the listening room 20, a pseudo reflected sound SRR1 from the right loudspeaker 12R allows the sound image 22, such as a vocalist, to be localized at substantially the center between the right and left loudspeakers 12R and 12L.

The reproduction characteristic adjuster 7 may further include a pseudo-reverberant-sound adding circuit 25 for adding pseudo-reverberant-sound data. A pseudo reverberant sound is added to the reproduced sounds from the right loudspeaker 12R, thus allowing more natural localization of the sound image 22, such as a vocalist.

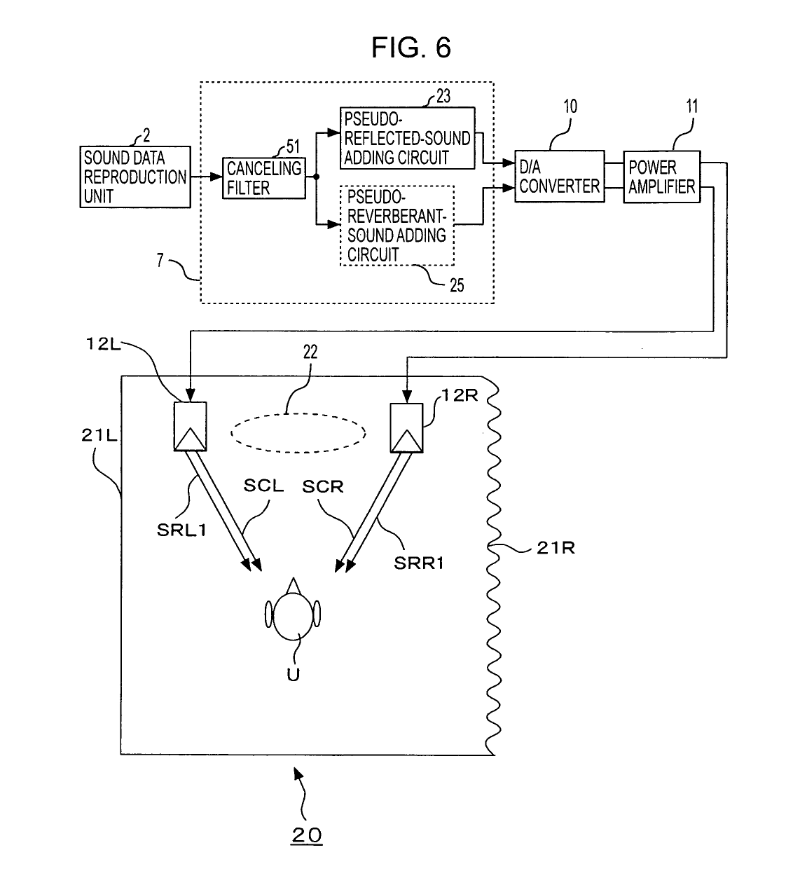

Alternatively, the reproduction characteristic adjuster 7 may have an arrangement shown in FIG. 6.

The reproduction characteristic adjuster 7 shown in FIG. 6 includes a canceling filter 51 and a pseudo-reflected-sound adding circuit 23. After the canceling filter 51 cancels reproduced sounds (SCR and SCL) from the right and left loudspeakers 12R and 12L in the listening room 20, the acoustic characteristic of the desired reflected sound or the like is added. That is, after applying the reverse characteristic so that the transfer characteristic from the loudspeakers 12R and 12L to the listening point exhibits a flat frequency characteristic, the acoustic characteristic of the desired reflected sound is added by the pseudo-reflected-sound adding circuit 23.

Therefore, if the reflected sound SRR is not reflected from the right wall 21R of the listening room 20, a pseudo reflected sound SRL1 from the left loudspeaker 12L and a pseudo reflected sound SRR1 from the right loudspeaker 12R allow the sound image 22, such as a vocalist, to be localized at substantially the center between the right and left loudspeakers 12R and 12L, and also allow for natural sound expansion.

The reproduction characteristic adjuster 7 may further include a pseudo-reverberant-sound adding circuit 25 for adding pseudo-reverberant-sound data. A pseudo reverberant sound is added to the reproduced sounds from the right and left loudspeakers 12R and-12L, thus allowing more natural localization of the sound image 22.

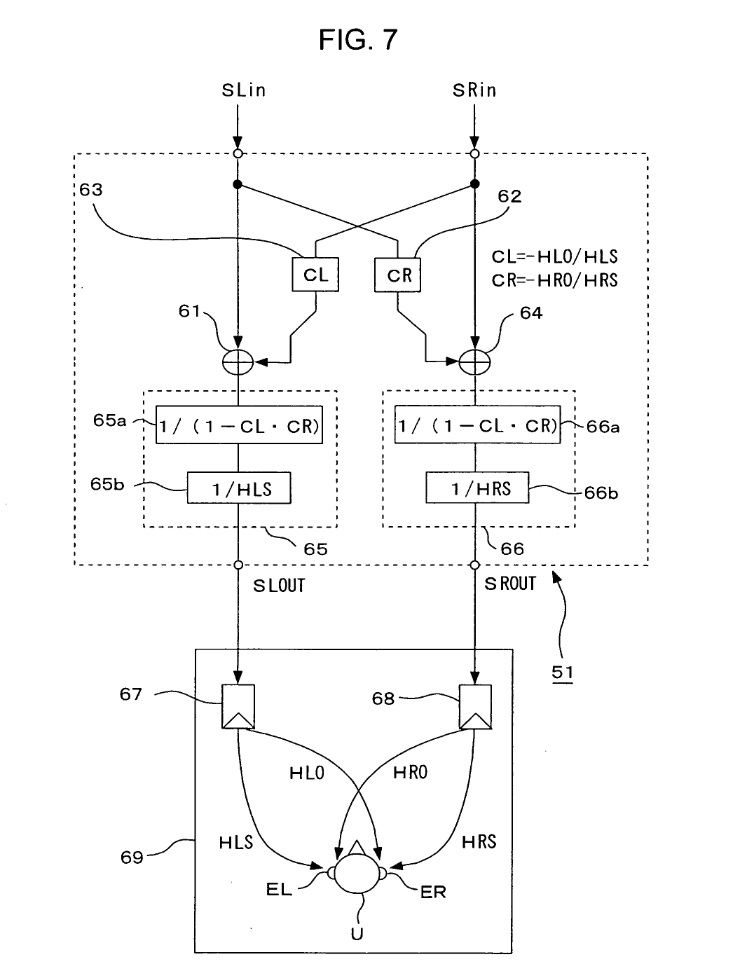

The canceling filter 51 will be described with reference to FIG. 7.

FIG. 7 shows a reproduced sound field space 69 having the head diffraction transfer function HLS from a left loudspeaker 67 to the left ear EL of a listener U, the head diffraction transfer function HRS from a right loudspeaker 68 to the right ear ER of the listener U. The reproduced sound field space 69 also has the head diffraction transfer function HLO from the left loudspeaker 67 to the right ear ER of the listener U, and the head diffraction transfer function HRO from the right loudspeaker 68 to the left ear EL of the listener U.

The canceling filter 51 shown in FIG. 7 receives a left collected sound signal SLin as a left-channel signal and a right collected sound signal SRin as a right-channel signal from a dummy-head microphone (not shown).

The left-channel collected sound signal SLin is input to an adder 61 and a crosstalk canceller 62. The right-channel collected sound signal SRin is input to an adder 64 and a crosstalk canceller 63.

The crosstalk cancellers 62 and 63 are filters for canceling the crosstalk component from the left loudspeaker 67 to the right ear ER of the listener U and the crosstalk component from the right loudspeaker 68 to the left ear EL of the listener U, respectively.

The crosstalk canceller 62 has a transfer characteristic CR given by -HRO/HRS, and the crosstalk canceller 63 has a transfer characteristic CL given by -HLO/HLS.

The left-channel collected sound signal SLin passed through the crosstalk canceller 62 is input to the adder 64 as a canceling signal. The right-channel collected sound signal SRin passed through the crosstalk canceller 63 is input to the adder 61 as a canceling signal.

The adder 61 calculates the sum of the input left-channel collected sound signal SLin and the canceling signal from the crosstalk canceller 63, and output the resulting signal to a correction block 65.

The adder 64 calculates the sum of the input right-channel collected sound signal SRin and the canceling signal from the crosstalk canceller 62, and outputs the result to a correction block 66.

The correction block 65 is configured to correct a left-channel reproduction system including the left loudspeaker 67. The correction block 65 includes a corrector 65a for correcting for a change in the characteristic caused by the crosstalk canceller 63, and a loudspeaker corrector 65b for correcting the loudspeaker characteristic. The transfer characteristic of the corrector 65a is defined by 1/(1−CL·CR). The transfer characteristic of the corrector 65b is defined by 1/HLS. The output signal of the correction block 65 is output from the canceling filter 51 as a left-channel collected sound signal SLout.

The correction block 66 is configured to correct a right-channel reproduction system including the right loudspeaker 68. The correction block 66 includes a corrector 66a for correcting for a change in the characteristic caused by the crosstalk canceller 62, and a loudspeaker corrector 66b for correcting the loudspeaker characteristic. The transfer characteristic of the corrector 66a is defined by 1/(1−CL·CR). The transfer characteristic of the corrector 66b is defined by 1/HRS. The output signal of the correction block 66 is output from the canceling filter 51 as a right-channel collected sound signal SRout.

The left-channel collected sound signal SLout output from the canceling filter 51 is input to the left loudspeaker 67 in the reproduced sound field space 69, and the right-channel collected sound signal SRout is input to the right loudspeaker 68. Thus, in the reproduced sound field space 69, only the left-ear sound corresponding to the left-channel collected sound signal SLin input to the canceling filter 51 is reproduced in the left ear EL of the listener U, and only the right-ear sound corresponding to the right-channel collected sound signal SRin input to the canceling filter 51 is reproduced in the right ear ER of the listener U.

In the sound reproducing apparatus 1 according to the present embodiment, sound data and meta-data indicating the target space properties for reproduction of the sound data are stored in a recording medium. However, this meta-data may not be recorded in the recording medium.

For example, a content identification code may be recorded in the recording medium, and meta-data corresponding to the content identification code may be stored in a database on a network.

A sound reproducing apparatus according another embodiment of the present invention will now be described. In this embodiment, meta-data corresponding to a content identification code recorded in a recording medium is stored in a database or the like on a network.

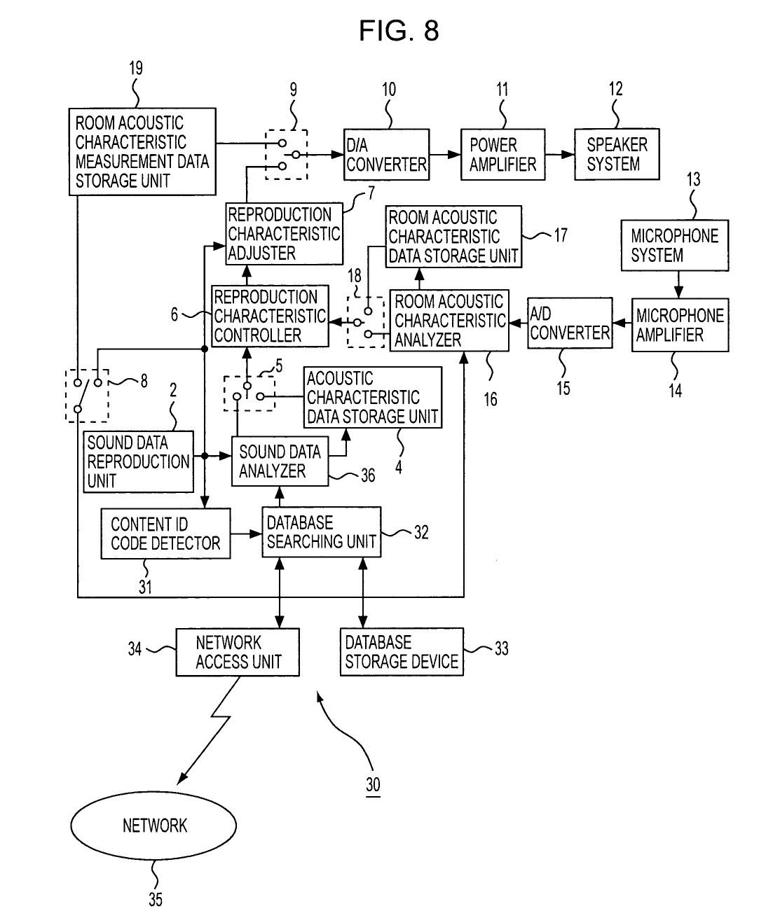

FIG. 8 is a block diagram of a sound reproducing apparatus 30 according to another embodiment of the present invention.

In FIG. 8, the same components as those of the sound reproducing apparatus 1 shown in FIG. 1 are assigned the same reference numerals, and a description thereof is omitted.

In the sound reproducing apparatus 30 shown in FIG. 8, a content identification (ID) code detector 31 detects a content ID code recorded in a recording medium from sound data output from the sound data reproduction unit 2.

A database searching unit 32 searches a database for meta-data corresponding to the content ID code detected by the content ID code detector 31.

For example, if the content ID code and the meta-data are stored in a database storage device 33 of the sound reproducing apparatus 30, the database searching unit 32 retrieves this meta-data from the database storage device 33.

If the meta-data is not stored in the database storage device 33, a network access unit 34 is controlled so as to retrieve the meta-data corresponding to the content ID code from a database on a network 35, and stores the retrieved meta-data and the content ID code in the database storage device 33.

A sound data analyzer 36 analyzes the meta-data searched for from the database by the database searching unit 32, and determines an acoustic characteristic of a listening room so as to provide the optimum reproduction of the sound data recorded in the recording medium.

Therefore, the sound reproducing apparatus 30 also allows an acoustic characteristic adjustment for the reproduced sound data based on the room acoustic characteristic of the listening room 20 and the meta-data corresponding to the sound data recorded in the recording medium. Thus, if music sources having different recording environments and various categories are reproduced in a listening room, an adjustment to an optimum acoustic characteristic for each music source can automatically be performed for sound reproduction.

A content ID code for identifying content, such as sound data, recorded in a recording medium may not be data that is recorded to identify the content, and may be any other data having extremely low probability of the existence of the same combination of values, such as table-of-contents (TOC) data of a compact disk (CD) or as a portion of song signal data.

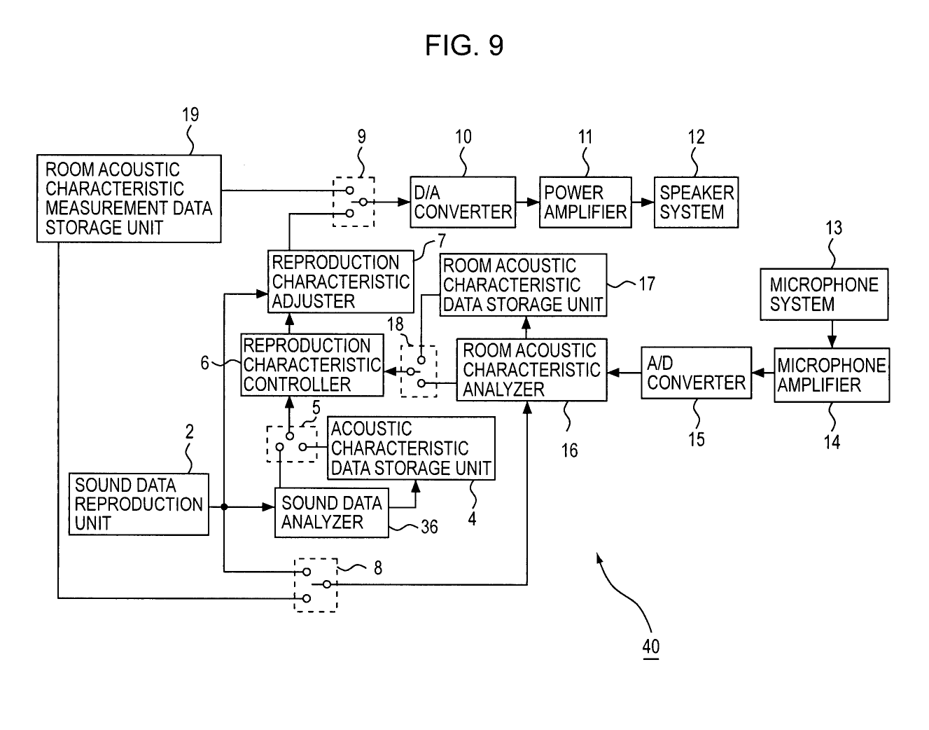

FIG. 9 is a block diagram of a sound reproducing apparatus 40 according to another embodiment of the present invention. In FIG. 9, the same components as those of the sound reproducing apparatus 1 or 30 shown in FIG. 1 or 8 are assigned the same reference numerals, and a description thereof is omitted.

In the sound reproducing apparatus 40 shown in FIG. 9, a sound data analyzer 36 analyzes the properties of the sound data reproduced by the sound data reproduction unit 2, and a room acoustic characteristic of an acoustic space in which the sound data was recorded or a virtual acoustic space in which the sound data is to be played back.

For example, the sound data analyzer 36 analyzes the timing or magnitude of the reflected sound based on the shape of the self-cross-correlation coefficient or the cepstrum of the sound signal, and analyzes the expansion of the sound image based on the inter-channel cross-correlation function.

The sound data analyzer 36 preferably has a sub-band filtering function for analyzing the reflected sound in frequency bands when the sound data is analyzed.

The analysis result of the sound data analyzer 36 may be stored in the sound characteristic data storage unit 4 for, for example, each content ID code so that it can be retrieved each time the content is selected.

Therefore, the sound reproducing apparatus 40 also allows an acoustic characteristic adjustment for the reproduced sound data based on the room acoustic characteristic of the listening room 20 and the acoustic characteristic obtained from the sound data recorded in the recording medium. Thus, if music sources having different recording environments and various categories are reproduced in a listening room, an adjustment to an optimum acoustic characteristic for each music source can automatically be performed for sound reproduction.

The illustrated embodiments are merely examples, and the present invention may be implemented by any other sound reproducing apparatus that allows an acoustic characteristic adjustment based on the acoustic characteristic corresponding to reproduction data to be reproduced from a recording medium and a room acoustic characteristic of a listening room.

In the illustrated embodiments, the recording medium is implemented as an optical disk. However, the present invention is not limited thereto, and the recording medium may include, for example, a Blu-ray disk, a CD, a Mini Disc, a hard disk drive (HDD), or a memory card, e.g., a Flash memory.

1. A sound reproducing method comprising:
obtaining an acoustic characteristic of a space in which sound data is to be reproduced;
obtaining a target acoustic characteristic of a reproduced sound field space associated with the sound data; and
performing an acoustic characteristic adjustment based on the acoustic characteristic of the space in which sound data is to be reproduced and the target acoustic characteristic of the reproduced sound field space when the sound data is reproduced.

2. A sound reproducing apparatus comprising:
sound data reproducing means for reproducing sound data;
acoustic characteristic obtaining means for obtaining a target acoustic characteristic of a reproduced sound field space associated with the sound data;
acoustic characteristic measuring means for measuring a room acoustic characteristic of a space in which the sound data is to be reproduced; and
acoustic characteristic adjusting means for performing an acoustic characteristic adjustment based on the room acoustic characteristic measured by the acoustic characteristic measuring means and the target acoustic characteristic obtained by the acoustic characteristic obtaining means when the sound data is reproduced.

3. The sound reproducing apparatus according to claim 2, wherein the acoustic characteristic measuring means comprises:
acoustic measurement sound outputting means for outputting an acoustic measurement sound to the space in which the sound data is to be reproduced; and
room acoustic characteristic determining means for determining the room acoustic characteristic of the space in which the sound data is to be reproduced based on the acoustic measurement sound.

4. The sound reproducing apparatus according to claim 2, wherein the acoustic characteristic measuring means comprises room acoustic characteristic determining means for determining the room acoustic characteristic of the space in which the sound is to be reproduced based on a reproduced sound reproduced by the sound data reproducing means in the space in which the sound data is to be reproduced.

5. The sound reproducing apparatus according to claim 2, wherein the acoustic characteristic obtaining means obtains the target acoustic characteristic from a recording medium having the sound data recorded therein.

6. The sound reproducing apparatus according to claim 2, wherein the acoustic characteristic obtaining means obtains the target acoustic characteristic via a network.

7. The sound reproducing apparatus according to claim 2, wherein the acoustic characteristic obtaining means obtains the target acoustic characteristic by analyzing the sound data.

8. A recording medium including sound data and a target acoustic characteristic of a sound field space in which the sound data is to be reproduced.
